(19) United States
(12) Patent Application Publication
(10) Pub. No.: US 2026/0214841 A1
(43) Pub. Date: Jul. 23, 2026

(54) CLOSED-LOOP DUAL RADIATOR COOLING DEVICE

(71) Applicant: AIC INC., Taoyuan City (TW)

(72) Inventors: Yen-Chih CHEN, Taoyuan City (TW); Yu-Xiang HUANG, Taoyuan City (TW); Hsin-Hao CHEN, Taoyuan City (TW)

(21) Appl. No.: 19/030,402

(22) Filed: Jan. 17, 2025

(51) Int. Cl. H05K 7/20

(52) U.S. Cl. CPC H05K 7/20272; H05K 7/20263; H05K 7/20781

(57) ABSTRACT

A closed-loop dual radiator cooling device having a liquid-cooling head, a first liquid-cooling radiator, a second liquid-cooling radiator, and a fan is provided. The liquid-cooling head has a hot port and a cold port. The first liquid-cooling radiator has a first inlet and a first outlet. The hot port is communicated to the first inlet. The second liquid-cooling radiator is arranged between the liquid-cooling head and the first liquid-cooling radiator and has a second inlet and a second outlet. A volume of the second liquid-cooling radiator is smaller than a volume of the first liquid-cooling radiator. The first outlet is communicated to the second inlet. The second outlet is communicated to the cold port. The fan is corresponding to the first liquid-cooling radiator and performs air cooling to the first liquid-cooling radiator. A cooling efficiency of a server is therefore improving within an existing space of the server.

### BACKGROUND

### Technical Field

The present disclosure relates to the field of server, particularly to a closed-loop dual radiator cooling device that may further enhance the cooling performance of the server within existing space.

### Description Of Related Art

Schools, companies or public institutions generally use the cabinet to install a plurality of servers for daily operations. In order to ensure that the servers may operate stably and normally within the operating temperature range, how to efficiently cool the interior of the cabinet is an extremely important issue. Therefore, the current cooling methods for the servers in the cabinet are mainly divided into two types: air-cooling and liquid-cooling. Air-cooling uses the airflow created by the fan to dissipate the heat energy generated by the server. Liquid cooling uses a liquid-cooling head attached directly to a heat source of the server and uses a pump to push a coolant from the liquid-cooling head to a liquid-cooling radiator to dissipate the heat energy.

However, with the increased performance of the server, the heat energy generated by various electronic components on the server has also increased significantly such that the heat dissipation of existing air-cooling or liquid-cooling is no longer able to meet the needs. In addition, because the size and the volume of the servers are fixed by specifications, the volume of the fan, the liquid-cooling head or the liquid-cooling radiator cannot be increased to improve the cooling effect. Therefore, how to design a cooling device may further enhance the cooling performance of the server within existing space is an urgently desired improvement.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to further enhance the cooling performance of the server within existing space.

To accomplish the aforementioned objective, the present disclosure provides a closed-loop dual radiator cooling device having a liquid-cooling head, a first liquid-cooling radiator, a second liquid-cooling radiator, and a fan. The liquid-cooling head has a hot port and a cold port. The first liquid-cooling radiator has a first inlet and a first outlet. The hot port is communicated to the first inlet. The second liquid-cooling radiator is arranged between the liquid-cooling head and the first liquid-cooling radiator and has a second inlet and a second outlet. The second inlet is communicated to the first outlet. The second outlet is communicated to the cold port. A volume of the second liquid-cooling radiator is smaller than a volume of the first liquid-cooling radiator. The fan is corresponding to the first liquid-cooling radiator and performs air cooling to the first liquid-cooling radiator. The first liquid-cooling radiator is located between the fan and the second liquid-cooling radiator.

Another aspect of the present disclosure provides that further includes a first infusion tube, a second infusion tube, and a third infusion tube, the first infusion tube is connected between the hot port and the first inlet, the second infusion tube is connected to the first outlet and the second inlet, the third infusion tube is connected to the second outlet and the cold port.

Another aspect of the present disclosure provides that the second liquid-cooling radiator is located between the first infusion tube, the second infusion tube, the third infusion tube, and the first liquid-cooling radiator.

Another aspect of the present disclosure provides that further includes a humidity detection assembly, the humidity detection assembly is arranged on a junction between two of the first infusion tube, the second infusion tube, and the third infusion tube to detect humidity changes at the junction.

Another aspect of the present disclosure provides that the humidity detection assembly includes a sealing box and a humidity sensor, the sealing box is arranged at the junction, the humidity sensor is accommodated in the sealing box and is configured to detect humidity changes in the sealing box.

Another aspect of the present disclosure provides that the sealing box includes a first cover and a second cover, the first cover is mounted to the second cover by fastening, buckling, or screwing.

Another aspect of the present disclosure provides that the first liquid-cooling radiator includes a first inlet tank, a plurality of first cooling pipelines, and a first outlet tank, each of the first cooling pipelines is connected between the first inlet tank and the first outlet tank, the first inlet tank has the first inlet, the first outlet tank has the first outlet, the second liquid-cooling radiator includes a second inlet tank, a plurality of second cooling pipelines, and a second outlet tank, each of the second cooling pipelines is connected between the second inlet tank and the second outlet tank, the second inlet tank has the second inlet, the second outlet tank has the second outlet.

Another aspect of the present disclosure provides that a volume of each of the first cooling pipelines is greater than a volume of each of the second cooling pipelines.

Another aspect of the present disclosure provides that the liquid-cooling head includes an upper cover, a divider plate, and a bottom plate, the divider plate is arranged between the upper cover and the bottom plate to separate an interior of the liquid-cooling head into an inlet chamber and an outlet chamber, the inlet chamber is communicated to the cold port, the outlet chamber is communicated to the hot port.

Another aspect of the present disclosure provides that the upper cover has a plurality of cooling fins, each of the cooling fins is arranged on two sides of the upper cover in a one-piece form with the upper cover.

In the closed-loop dual radiator cooling device of the present disclosure, the first liquid-cooling radiator, which is larger than the second liquid-cooling radiator, may perform preliminary heat dissipation to the coolant flowing out of the hot port of the liquid-cooling head in conjunction with the fan. The coolant then passes through the second liquid-cooling radiator for a second heat dissipation to effectively enhance the heat dissipation efficiency. Since the second liquid-cooling radiator is arranged between the liquid-cooling head and the first liquid-cooling radiator, and the first liquid-cooling radiator is located between the fan and the second liquid-cooling radiator, the closed-loop dual radiator cooling device may further enhance the cooling performance of the server within existing space without changing the size and volume of the server.

### BRIEF DESCRIPTION OF THE DRAWINGS

FIG. 1 is a top view of the present disclosure arranged on the server;

FIG. 2 is a perspective appearance view of the present disclosure;

FIG. 3 is an exploded view of the present disclosure;

FIG. 4 is an exploded view of the liquid-cooling radiator, the first infusion tube, and the humidity detection assembly of the present disclosure;

FIG. 5 is an exploded view of the first liquid-cooling radiator, the second infusion tube, the third infusion tube, and the humidity detection assembly of the present disclosure;

FIG. 6 is an exploded view of the liquid-cooling head of the present disclosure; and

FIG. 7 is a cross-sectional top view of the present disclosure.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

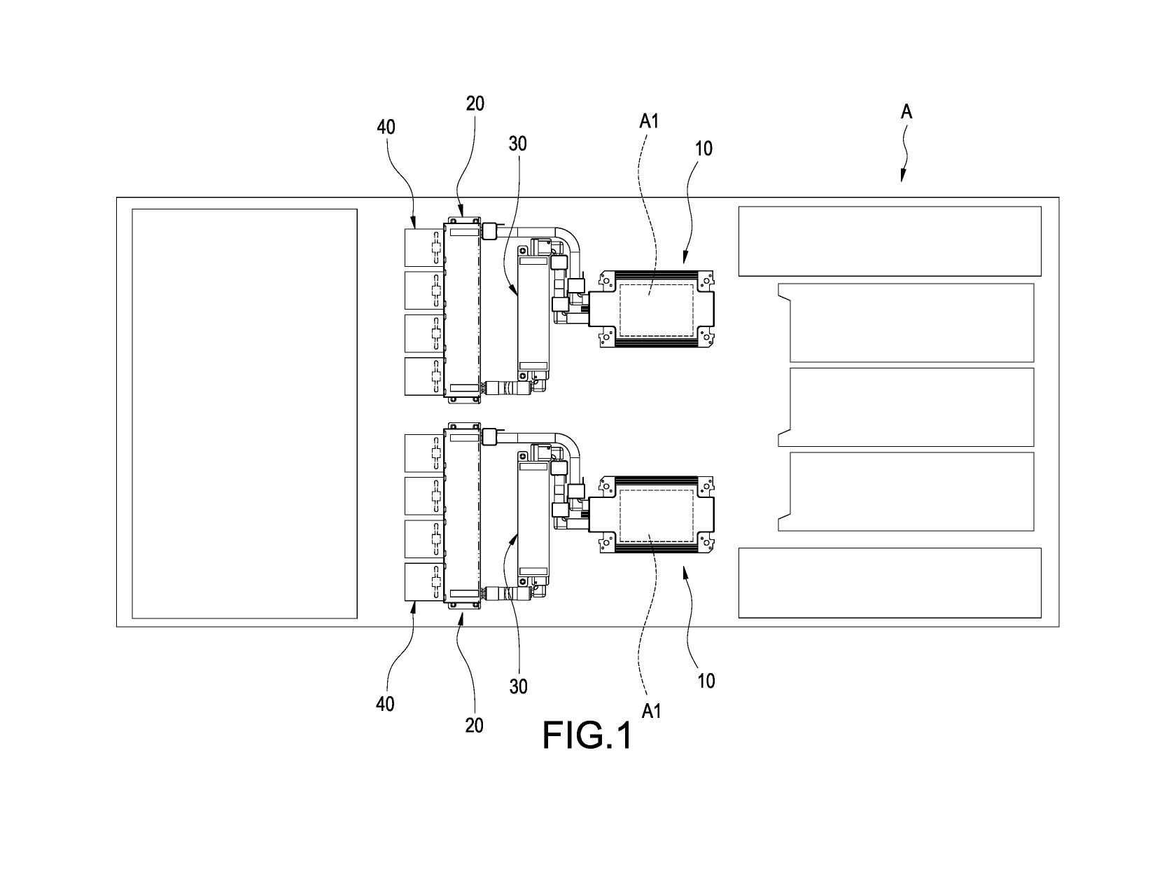

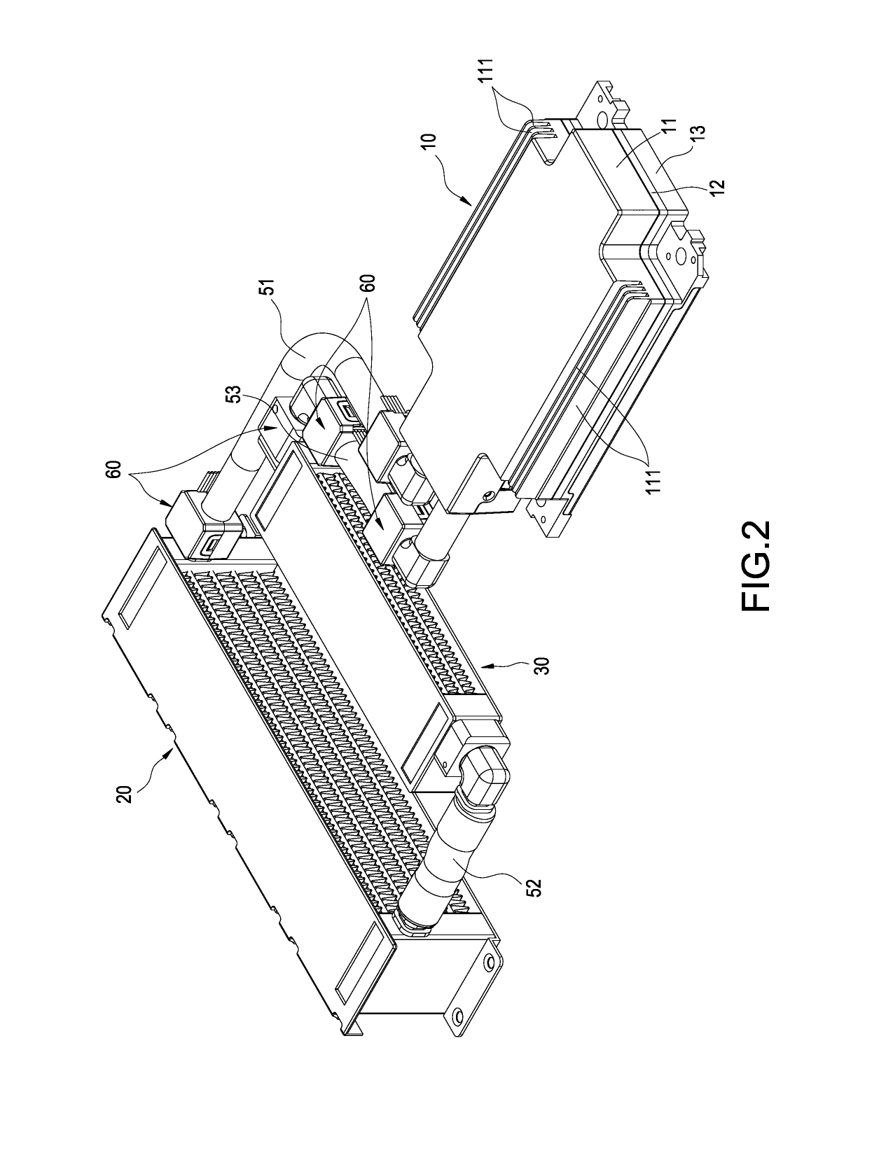

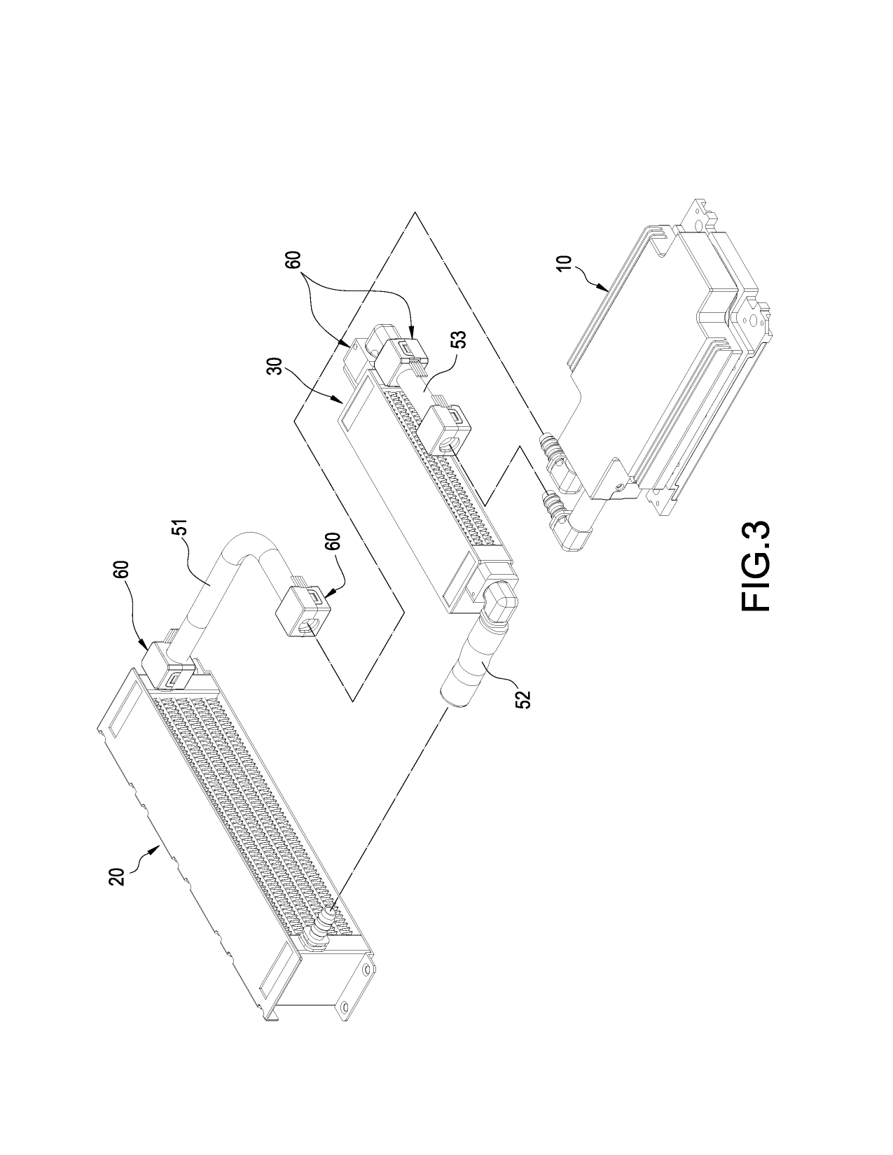

The present disclosure provides a closed-loop dual radiator cooling device, which is arranged on a server A and used to cooling at least one heat source A1 on the server A. In the embodiment, a number of the heat source A1 and a number of the closed-loop dual radiator cooling device both are two, but the present disclosure is not limited to this embodiment. The number of the heat source A1 may be modified according to different types of sizes of the server A, and the number of the closed-loop dual radiator cooling device may be modified according to the number of the heat source A1 that needs heat dissipation. For the convenience of description, only one heat source A1 and one closed-loop dual radiator cooling device are used in the following description. However, the present disclosure is not limited to only one heat source A1 and one closed-loop dual radiator cooling device. Please refer to FIG. 1, FIG. 2, and FIG. 3, the closed-loop dual radiator cooling device of the present disclosure mainly includes a liquid-cooling head 10, a first liquid-cooling radiator 20, a second liquid-cooling radiator 30, and a fan 40.

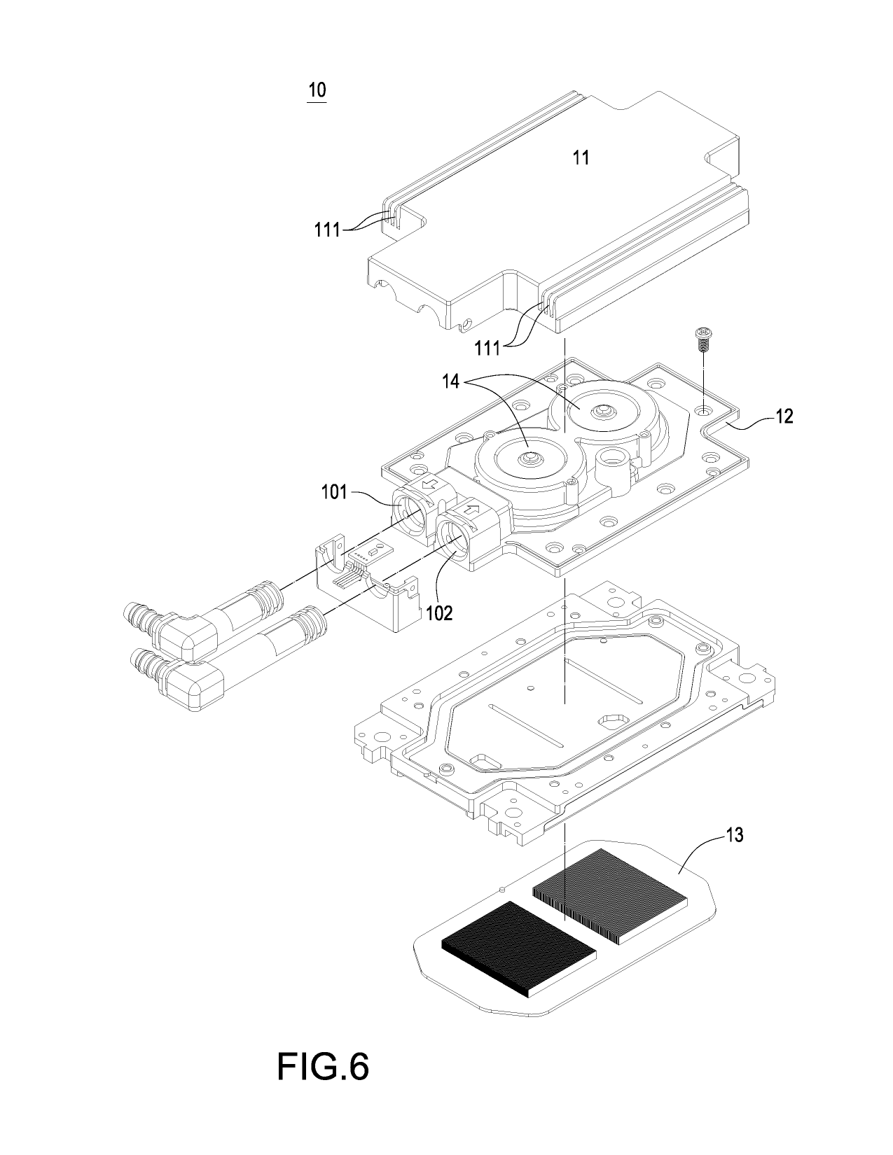

Please refer to FIG. 1 first. The liquid-cooling head 10 is attached on the heat source A1 of the server A to absorb a heat energy generated by the heat source A1 and transfer the heat energy to a coolant (not shown in figures) therein. Please refer to FIG. 2, FIG. 3, and FIG. 6. The liquid-cooling head 10 has a hot port 101 and a cold port 102. The hot port 101 is for the coolant to leave the liquid-cooling head 10 after absorbing the heat energy, and the cold port 102 is for the coolant to reenter the liquid-cooling head 10 after dissipating the heat energy. The liquid-cooling head 10 mainly includes an upper cover 11, a divider plate 12, and a bottom plate 13. The divider plate 12 is arranged between the upper cover 11 and the bottom plate 13 to separate an interior of the liquid-cooling head 10 into an inlet chamber 103 and an outlet chamber 104. The inlet chamber 103 is communicated to the cold port 102, and the outlet chamber 104 is communicated to the hot port 101. The bottom plate 13 is attached on the heat source A1 to absorb the heat energy generated by the heat source A1 and transfer the heat energy to the coolant inside the inlet chamber 103. The upper cover 11 has a plurality of cooling fins 111. Each of the cooling fins 111 is arranged on two sides of the upper cover 11 in a one-piece form with the upper cover 11 to efficiently dissipate heat from the liquid-cooling head 10 to prevent excessive temperature. In the embodiment, a pump 14 is arranged in the liquid-cooling head 10 to push the coolant to flow such that the coolant in the inlet chamber 103 may be pushed to flow into the outlet chamber 104, but the present disclosure is not limited to this embodiment. For example, the pump 14 may also be arranged outside the liquid-cooling head 10 and connected to the liquid-cooling head 10.

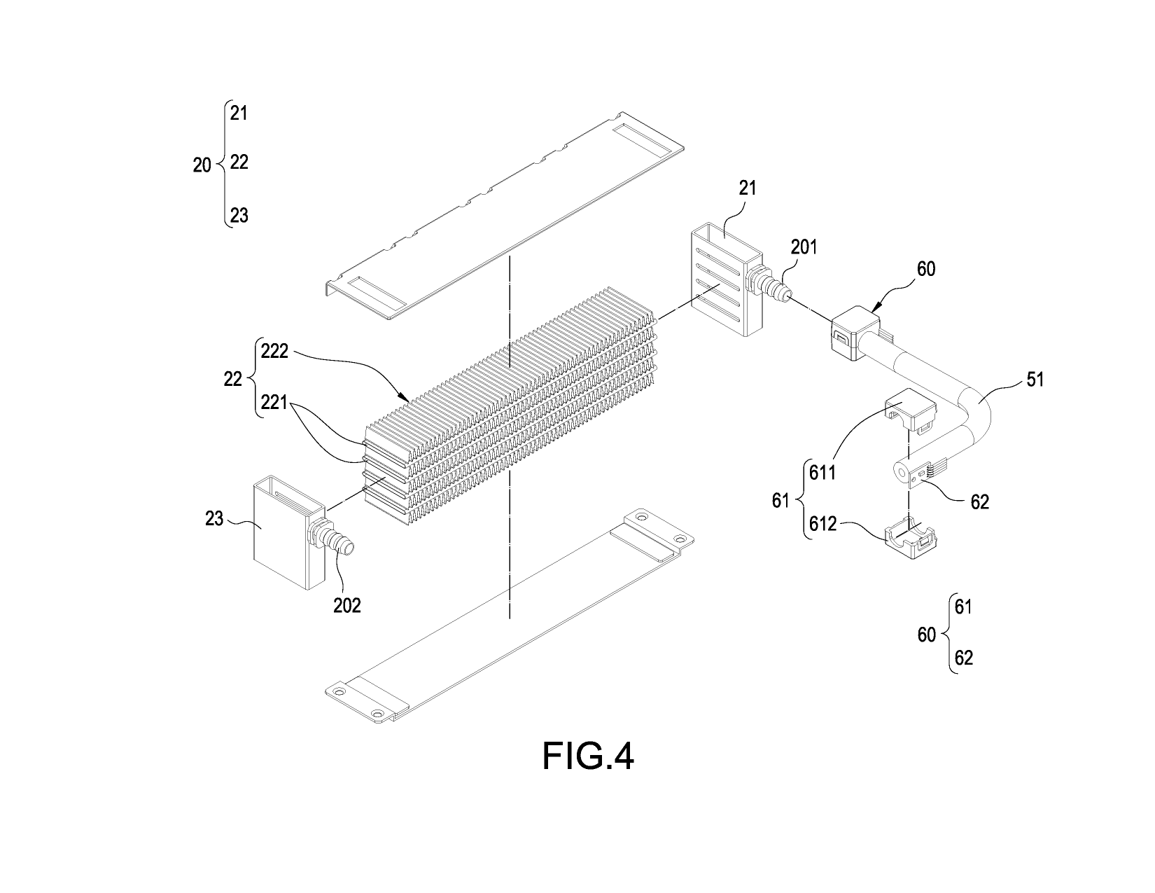

Please refer to FIG. 2, FIG. 3, and FIG. 4. The first liquid-cooling radiator 20 has a first inlet 201 and a first outlet 202. In detail, the first liquid-cooling radiator 20 includes a first inlet tank 21, a plurality of first cooling pipelines 22, and a first outlet tank 23. The first inlet tank 21 has the first inlet 201, and the first outlet tank 23 has the first outlet 202. The hot port 101 is communicated to the first inlet 201 such that the coolant may enter the first inlet tank 21 after leaving the liquid-cooling head 10. Each of the first cooling pipelines 22 is connected between the first inlet tank 21 and the first outlet tank 23 such that the coolant that enters the first inlet tank 21 may dissipate heat through the first cooling pipelines 22 and then enter the first outlet tank 23. The first cooling pipelines 22 include a plurality of first tubes 221 and a plurality of first fin groups 222. In the embodiment, each of the first tubes 221 is a flat tube, the first tubes 221 are arranged parallel to each other and spaced apart between the first fin groups 222, and each of the first fin groups 222 is composed of wavy metal fin. However, the present disclosure is not limited to this embodiment, the first tubes 221 and the first fin groups 222 may also be in other forms that are well known to the person having ordinary skill in the art.

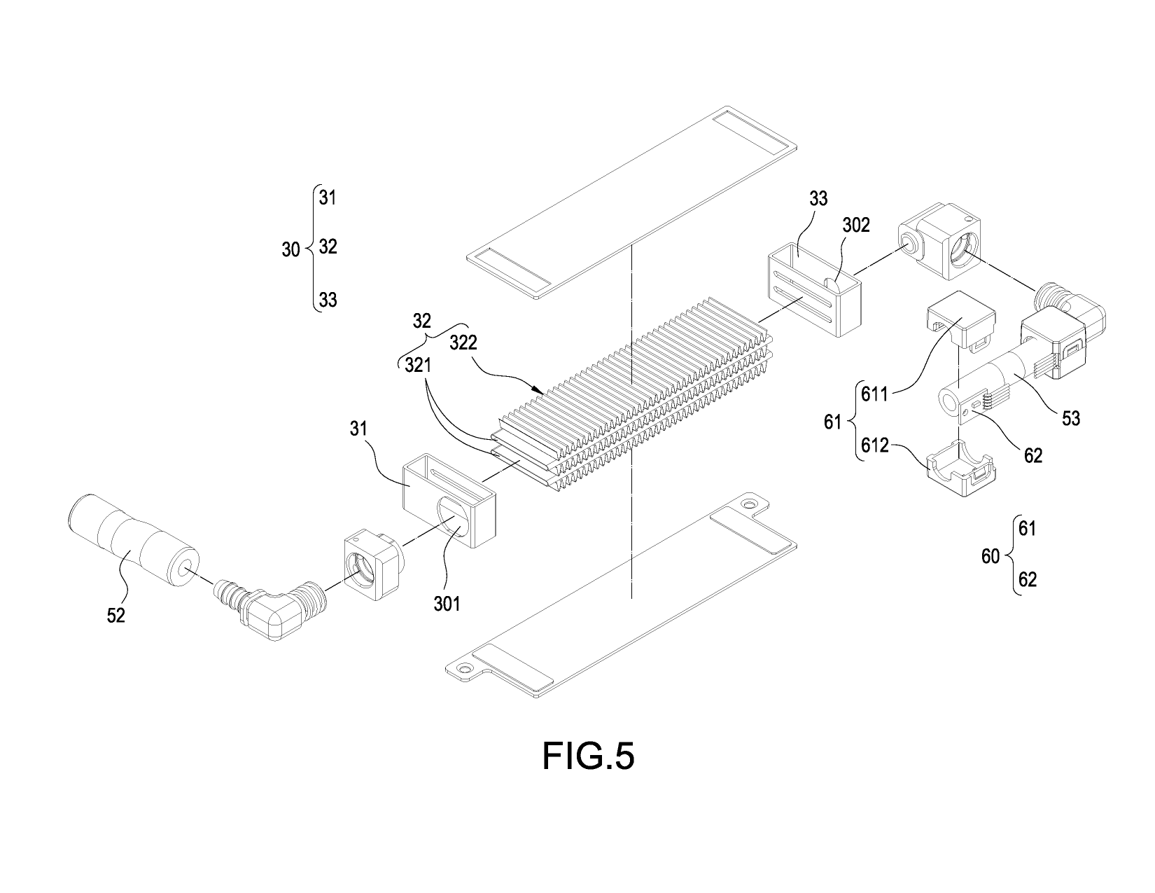

Please refer to FIG. 2, FIG. 3, and FIG. 5. The second liquid-cooling radiator 30 is arranged between the liquid-cooling head 10 and the first liquid-cooling radiator 20, and the second liquid-cooling radiator 30 is parallel to the first liquid-cooling radiator 20. A volume of the second liquid-cooling radiator 30 is smaller than a volume of the first liquid-cooling radiator 20. In the embodiment, a length, a width and a height of the second liquid-cooling radiator 30 are all smaller than a length, a width and a height of the first liquid-cooling radiator 20, but the present disclosure is not limited to this embodiment. The second liquid-cooling radiator 30 has a second inlet 301 and a second outlet 302. In detail, the second liquid-cooling radiator 30 includes a second inlet tank 31, a plurality of second cooling pipelines 32, and a second outlet tank 33. The second inlet tank 31 has the second inlet 301, the second outlet tank 33 has the second outlet 302. The first outlet 202 is communicated to the second inlet 301 such that the coolant may enter the second inlet tank 31 after leaving the first outlet tank 23. The second outlet 302 is communicated to the cold port 102 such that the coolant may enter the liquid-cooling head 10 after leaving the second outlet tank 33. Each of the second cooling pipelines 32 is connected between the second inlet tank 31 and the second outlet tank 33 such that the coolant that enters the second inlet tank 31 may dissipate heat through the second cooling pipelines 32 and then enter the second outlet tank 33. A volume of each of the second cooling pipelines 32 is smaller than a volume of each of the first cooling pipelines 22. The second cooling pipelines 32 include a plurality of second tubes 321 and a plurality of second fin groups 322. In the embodiment, each of the second tubes 321 is a flat tube, the second tubes 321 are arranged parallel to each other and spaced apart between the second fin groups 322, and each of the second fin groups 322 is composed of wavy metal fin. However, the present disclosure is not limited to this embodiment, the second tubes 321 and the second fin groups 322 may also be in other forms that are well known to the person having ordinary skill in the art.

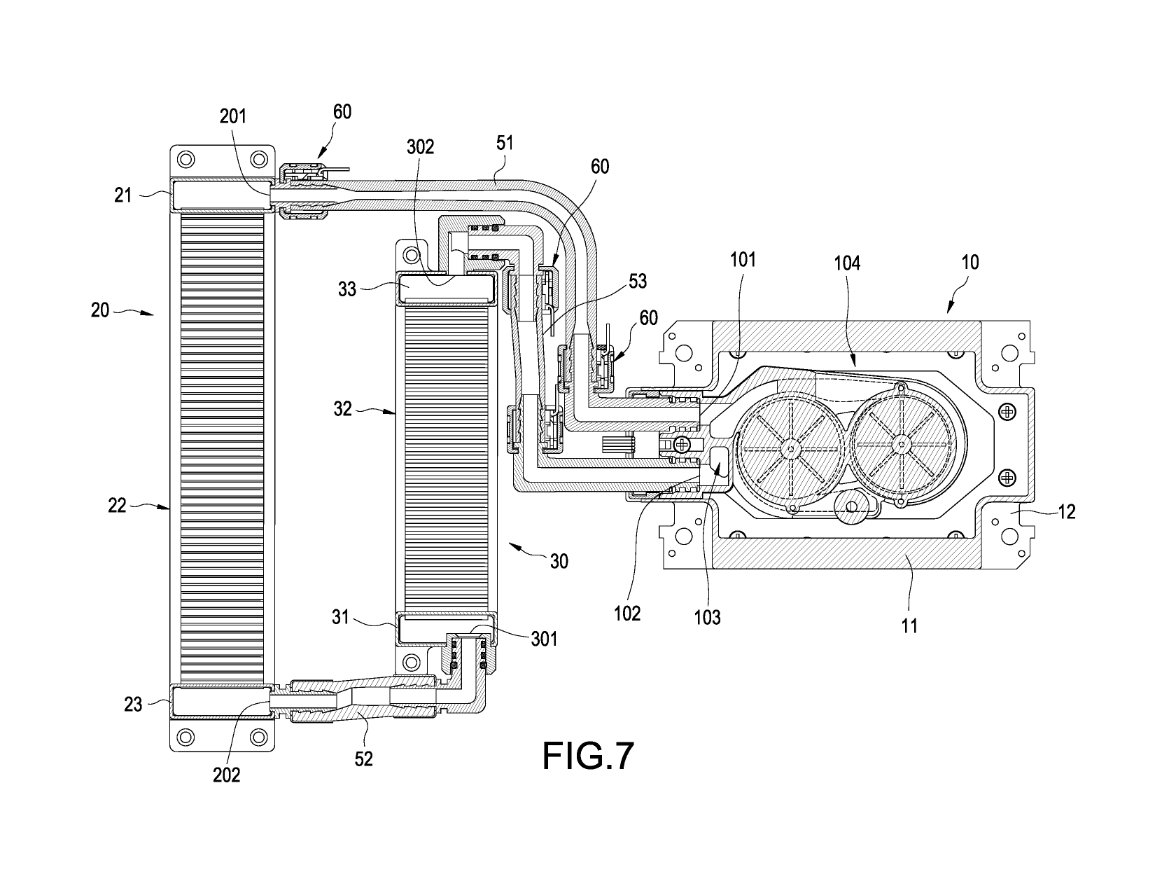

Please refer to FIG. 1 and FIG. 7. The fan 40 is corresponding to the first liquid-cooling radiator 20 and performs air cooling to the first liquid-cooling radiator 20 to achieve good heat dissipation. In the embodiment, a number of the fan 40 is in a plurality and the fans 40 are arranged side by side, but the present disclosure is not limited to this embodiment. The number of the fan 40 may be modified according to a length of the first liquid-cooling radiator 20. In other words, the number of the fan 40 is greater when the length of the first liquid-cooling radiator 20 is longer, so as to ensure the first cooling pipelines 22 of the first liquid-cooling radiator 20 may be blown by the fans 40 to dissipate heat. The first liquid-cooling radiator 20 is located between the fans 40 and the second liquid-cooling radiator 30. In detail, the first liquid-cooling radiator 20 is parallel to an arranging direction of the fans 40 and the second liquid-cooling radiator 30. Therefore, the arrangement of the second liquid-cooling radiator 30 will not affect the air-cooling effect that the fans 40 act on the first liquid-cooling radiator 20. In addition, since the volume of the second liquid-cooling radiator 30 is smaller than the volume of the first liquid-cooling radiator 20, the second liquid-cooling radiator 30 may be located between the liquid-cooling head 10 and the first liquid-cooling radiator 20 and perform secondary heat dissipation to the coolant after being dissipated heat by the first liquid-cooling radiator 20 rather than affects the existing size and the existing volume of the server A.

Please refer to FIG. 1, FIG. 2, FIG. 3, FIG. 4, and FIG. 5 again, the closed-loop dual radiator cooling device of the present disclosure further includes a first infusion tube 51, a second infusion tube 52, and a third infusion tube 53. The first infusion tube 51 is connected between the hot port 101 of the liquid-cooling head 10 and the first inlet 201 of the first liquid-cooling radiator 20. The second infusion tube 52 is connected to the first outlet 202 of the first liquid-cooling radiator 20 and the second inlet 301 of the second liquid-cooling radiator 30. The third infusion tube 53 is connected to the second outlet 302 of the second liquid-cooling radiator 30 and the cold port 102 of the liquid-cooling head 10. Therefore, the first infusion tube 51, the second infusion tube 52, and the third infusion tube 53 may connect the liquid-cooling head 10, the first liquid-cooling radiator 20, and the second liquid-cooling radiator 30 to efficiently transfer the coolant to form a loop. In addition, the second liquid-cooling radiator 30 is located between the first infusion tube 51, the second infusion tube 52, the third infusion tube 53, and the first liquid-cooling radiator 20, the arrangement of the second liquid-cooling radiator 30 is therefore enhancing the cooling performance without affecting the existing size and the existing volume of the server A. On the other hand, when the first liquid-cooling radiator 20 is enough to dissipate the heat energy, the user may detach the second liquid-cooling radiator 30 and make the first outlet 202 of the first liquid-cooling radiator 20 to be directly communicated to the cold port 102 of the liquid-cooling head 10 to form a loop.

Details are provided as follows. The closed-loop dual radiator cooling device of the present disclosure further includes at least one humidity detection assembly 60. The humidity detection assembly 60 is arranged on a junction between two of the first infusion tube 51, the second infusion tube 52, and the third infusion tube 53 to detect humidity changes at the junction. In detail, the humidity detection assembly 60 includes a sealing box 61 and a humidity sensor 62. The sealing box 61 is detachably arranged at the junction between two of the first infusion tube 51, the second infusion tube 52, and the third infusion tube 53. The sealing box 61 includes a first cover 611 and a second cover 612 mounted to each other to form a sealing space (not labeled in figures) inside the sealing box 61. The first cover 611 may be mounted to the second cover 612 by fastening, buckling, or screwing. In the embodiment, the first cover 611 is mounted to the second cover 612 by buckling such that the user may easily and quickly assemble or detach the sealing box 61. The humidity sensor 62 is accommodated in the sealing space of the sealing box 61 and is configured to detect humidity changes in the sealing box 61. In detail, since the junction is located in the sealing space of the sealing box 61, the moisture is less likely to be leaked or seeped and cause increased humidity inside the sealing space when the coolant is leaking or seeping at the junction. Therefore, the humidity may be detected by the humidity sensor 62 to alert the user, so as to avoid excessive leakage of the coolant causing insufficient water or damage to the electronic components on the server A.

In the embodiment, a number of the humidity detection assembly 60 is in a plurality, and the humidity detection assemblies 60 are respectively arranged on the junctions of the first infusion tube 51, the second infusion tube 52, and the third infusion tube 53 to detect whether the coolant is leaked or seeped of at the junctions such that the user may learn about it as soon as possible and handle it properly. However, the present disclosure does not specifically limit the number of the humidity detection assembly 60, the number and location of the humidity detection assemblies 60 may be modified according to different needs.

In the closed-loop dual radiator cooling device of the present disclosure, the first liquid-cooling radiator 20, which is larger than the second liquid-cooling radiator 30, may perform preliminary heat dissipation to the coolant flowing out of the hot port 101 of the liquid-cooling head 10 in conjunction with the fans 40. The coolant then passes through the second liquid-cooling radiator 30 for a second heat dissipation to effectively enhance the heat dissipation efficiency. Since the second liquid-cooling radiator 30 is arranged between the liquid-cooling head 10 and the first liquid-cooling radiator 20, and the first liquid-cooling radiator 20 is located between the fans 40 and the second liquid-cooling radiator 30, the closed-loop dual radiator cooling device may further enhance the cooling performance of the server A within existing space without changing the size and volume of the server A.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A closed-loop dual radiator cooling device, comprising:
a liquid-cooling head, comprising a hot port and a cold port;
a first liquid-cooling radiator, comprising a first inlet and a first outlet, the hot port communicated to the first inlet;
a second liquid-cooling radiator, arranged between the liquid-cooling head and the first liquid-cooling radiator and comprising a second inlet and a second outlet, the second inlet communicated to the first outlet, the second outlet communicated to the cold port, wherein a volume of the second liquid-cooling radiator is smaller than a volume of the first liquid-cooling radiator; and
a fan, corresponding to the first liquid-cooling radiator and performing air cooling to the first liquid-cooling radiator, wherein the first liquid-cooling radiator is located between the fan and the second liquid-cooling radiator.

2. The closed-loop dual radiator cooling device according to claim 1, further comprising a first infusion tube, a second infusion tube, and a third infusion tube, wherein the first infusion tube is connected between the hot port and the first inlet, the second infusion tube is connected to the first outlet and the second inlet, the third infusion tube is connected to the second outlet and the cold port.

3. The closed-loop dual radiator cooling device according to claim 2, wherein the second liquid-cooling radiator is located between the first infusion tube, the second infusion tube, the third infusion tube, and the first liquid-cooling radiator.

4. The closed-loop dual radiator cooling device according to claim 2, further comprising a humidity detection assembly, wherein the humidity detection assembly is arranged on a junction between two of the first infusion tube, the second infusion tube, and the third infusion tube to detect humidity changes at the junction.

5. The closed-loop dual radiator cooling device according to claim 4, wherein the humidity detection assembly comprises a sealing box and a humidity sensor, the sealing box is arranged at the junction, the humidity sensor is accommodated in the sealing box and is configured to detect humidity changes in the sealing box.

6. The closed-loop dual radiator cooling device according to claim 5, wherein the sealing box comprises a first cover and a second cover, the first cover is mounted to the second cover by fastening, buckling, or screwing.

7. The closed-loop dual radiator cooling device according to claim 1, wherein the first liquid-cooling radiator comprises a first inlet tank, a plurality of first cooling pipelines, and a first outlet tank, each of the first cooling pipelines is connected between the first inlet tank and the first outlet tank, the first inlet tank comprises the first inlet, the first outlet tank comprises the first outlet, the second liquid-cooling radiator comprises a second inlet tank, a plurality of second cooling pipelines, and a second outlet tank, each of the second cooling pipelines is connected between the second inlet tank and the second outlet tank, the second inlet tank comprises the second inlet, the second outlet tank comprises the second outlet.

8. The closed-loop dual radiator cooling device according to claim 7, wherein a volume of each of the first cooling pipelines is greater than a volume of each of the second cooling pipelines.

9. The closed-loop dual radiator cooling device according to claim 1, wherein the liquid-cooling head comprises an upper cover, a divider plate, and a bottom plate, the divider plate is arranged between the upper cover and the bottom plate to separate an interior of the liquid-cooling head into an inlet chamber and an outlet chamber, the inlet chamber is communicated to the cold port, the outlet chamber is communicated to the hot port.

10. The closed-loop dual radiator cooling device according to claim 9, wherein the upper cover comprises a plurality of cooling fins, each of the cooling fins is arranged on two sides of the upper cover in a one-piece form with the upper cover.
